(19) United States
(12) Patent Application Publication
(10) Pub. No.: US 2003/0098177 A1
(43) Pub. Date: May 29, 2003

(54) Multi-layer circuit board

(75) Inventor: Yu-Chiang Cheng, Taipei City (TW)

Correspondence Address: MERCHANT & GOULD P.C., P.O. Box 2903, Minneapolis, MN, 55402-0903, US

(73) Assignee: MITAC INTERNATIONAL CORP.

(21) Appl. No.: 09/995,200

(22) Filed: Nov. 26, 2001

(51) Int. Cl. H01L 23/495; H01L 23/053; H01L 23/12; H01L 23/48; H01L 29/40

(52) U.S. Cl. 174/261; 257/668; 257/700; 257/701; 257/758

(57) ABSTRACT

A multi-layer circuit board includes ground and power metal layers, signal wiring layers, and a plurality of insulating substrates disposed sequentially one above the other. Each adjacent pair of the metal layers and the signal wiring layers are spaced apart by one of the insulating substrates. At least one of the signal wiring layers is suitable for high-speed low-impedance signal transmission, and is separated from the adjacent one of the metal layers by an adjacent one of the insulating substrates, which is made from a first insulator material having a first dielectric coefficient. The other ones of the insulating substrates, that are not adjacent to the high-speed low-impedance signal wiring layers, are made of a second insulator material having a second dielectric coefficient lower than the first dielectric coefficient.

### BACKGROUND OF THE INVENTION

1. Field of the Invention

The invention relates to a circuit board, more particularly to a multi-layer circuit board which utilizes insulator materials with different dielectric coefficients to achieve characteristics suitable for high-speed low-impedance signal transmission.

2. Description of the Related Art

Referring to FIG. 1, a conventional 1.6 mm multi-layer circuit board is shown to comprise: first, second and third insulating substrates (A1), (A2), (A3) disposed sequentially one above the other; a first signal wiring layer (S1) disposed on one side of the first insulating substrate (A1) opposite to the second insulating substrate (A2); a power metal layer (PWR) disposed between the first and second insulating substrates (A1), (A2); a ground metal layer disposed between the second and third insulating substrates (A2), (A3); and a second signal wiring layer (S2) disposed on one side of the third insulating substrate (A3) opposite to the second insulating substrate (A2). The second insulating substrate (A2) is a thin core, whereas the first and third insulating substrates (A1), (A3) are prepreg layers. The second insulating substrate (A2) has a thickness (H1) of about 47 mil. Each of the first and third insulating substrates (A1), (A3) has a thickness (H2) of about 5 mil. Each of the first, second and third insulating substrates (A1), (A2), (A3) is generally made from glass fiber reinforced resin, the dielectric coefficient of which is about 4.5.

In the conventional multi-layer circuit board, the signal wiring layers (S1), (S2), in addition to being adapted for mounting with electronic components thereon, are provided with multiple traces for electrical connection with the electronic components mounted thereon and for forming electrical paths that connect the circuit board to other devices. The signal transmission quality along these traces is affected by the resistances of the first and second signal wiring layers (S1), (S2) with respect to the adjacent one of the power metal layer (PWR) and the ground metal layer (GND) As the first and second signal wiring layers (S1), (S2) are symmetrically disposed on the circuit board, the resistances thereof relative to the respective one of the power metal layer (PWR) and the ground metal layer (GND) are equal. With further reference to FIG. 2, the relative resistance of the first signal wiring layer (S1), and hence that of the second signal wiring layer (S2), is calculated using the following formula (1):

Z₀=87(E+1.414)^{-1/2} ln{5.98H/(0.8W+T)} (1)

wherein E is the dielectric coefficient of the adjacent insulating substrate and is equal to 4.5, H is the thickness of the adjacent insulating substrate and is equal to 5 mil, W is the width of traces of the signal wiring layer and is equal to 5 mil, and T is the thickness of the signal wiring layer and is equal to 0.7 mil.

After applying the aforesaid formula (1) to the conventional multi-layer circuit board of FIG. 1, it is found that Z₀ is equal to 60 ohms.

According to Intel, the resistances of high-speed low-impedance signal wiring layers relative to metal layers in a multi-layer circuit board should be within the range 28±10% ohms so as to be applicable to RAMBUS DRAM layouts, etc. If the resistances are to be reduced from 60 ohms to 28 ohms in the aforesaid conventional multi-layer circuit board, the width (W) has to be increased to 21 mil based on the above formula (1). Moreover, as the distance (S) between adjacent traces of the signal wiring layer preferably has a ratio of 1:1 with the width (W) in order to minimize signal interference, the distance (S) has to be 21 mil as well. In view of the current trend toward miniaturization of circuit boards, such dimensions are not desirable.

### SUMMARY OF THE INVENTION

Therefore, the main object of the present invention is to provide a multi-layer circuit board which utilizes insulator materials with different dielectric coefficients to achieve characteristics suitable for high-speed low-impedance signal transmission.

Another object of the present invention is to provide a multi-layer circuit board which utilizes insulator materials with different dielectric coefficients to reduce relative impedance and permit dense arrangement of traces of signal wiring layers.

A further object of the present invention is to provide a multi-layer circuit board which utilizes insulator materials with different dielectric coefficients so that relative impedances of signal wiring layers can be reduced while maintaining a total thickness that complies with manufacturing standards in the industry.

Accordingly, a multi-layer circuit board of this invention includes: at least two metal layers and at least two signal wiring layers disposed one above the other, at least one of the metal layers being a ground metal layer, at least one of the metal layers being a power metal layer; and a plurality of insulating substrates disposed sequentially one above the other, each adjacent pair of the metal layers and the signal wiring layers being spaced apart by one of the insulating substrates. At least one of the signal wiring layers is suitable for high-speed low-impedance signal transmission, has a resistance relative to an adjacent one of the metal layers that is within the range of 25.2 to 30.8 ohms, and is separated from the adjacent one of the metal layers by an adjacent one of the insulating substrates, which is made from a first insulator material having a first dielectric coefficient. The other ones of the insulating substrates, that are not adjacent to the high-speed low-impedance signal wiring layers, are made of a second insulator material having a second dielectric coefficient lower than the first dielectric coefficient.

### BRIEF DESCRIPTION OF THE DRAWINGS

Other features and advantages of the present invention will become apparent in the following detailed description of the preferred embodiments with reference to the accompanying drawings, of which:

FIG. 1 is a fragmentary schematic sectional view of a conventional multi-layer circuit board;

FIG. 2 is an enlarged schematic sectional view of the conventional multi-layer circuit board in part;

FIG. 3 is a fragmentary schematic sectional view of the first preferred embodiment of a multi-layer circuit board according to the present invention;

FIG. 4 is a fragmentary schematic view of the second preferred embodiment of a multi-layer circuit board according to the present invention;

FIG. 5 is a fragmentary sectional view of the second preferred embodiment;

FIG. 6 is a fragmentary schematic view of the third preferred embodiment of a multi-layer circuit board according to the present invention;

FIG. 7 is a fragmentary sectional view of the third preferred embodiment;

FIG. 8 is a fragmentary schematic view of the fourth preferred embodiment of a multi-layer circuit board according to the present invention;

FIG. 9 is a fragmentary schematic view of the fifth preferred embodiment of a multi-layer circuit board according to the present invention; and

FIG. 10 is a fragmentary schematic view of the sixth preferred embodiment of a multi-layer circuit board according to the present invention.

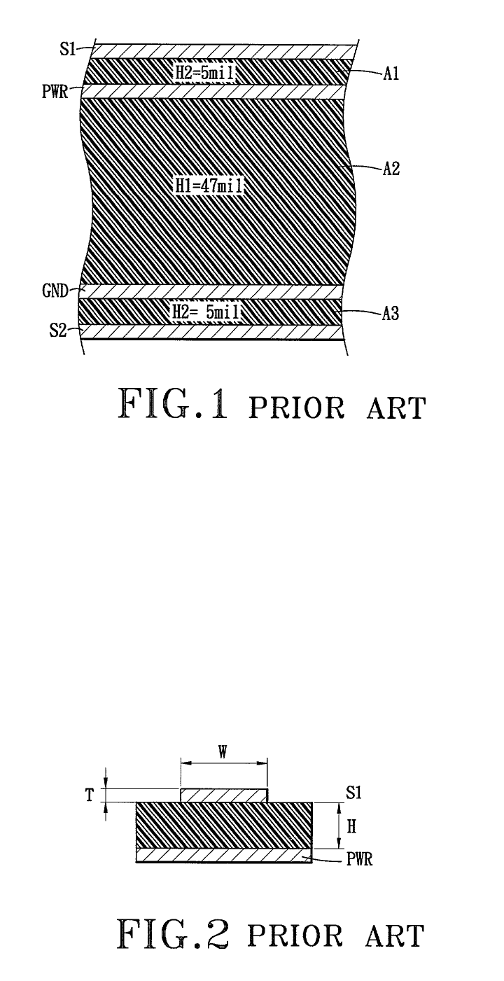

### DETAILED DESCRIPTION OF THE PREFERRED EMBODIMENTS

Before the present invention is described in greater detail, it should be noted that the dimensions of the various layers of the multi-circuit boards as illustrated in the accompanying drawings are not drawn to scale.

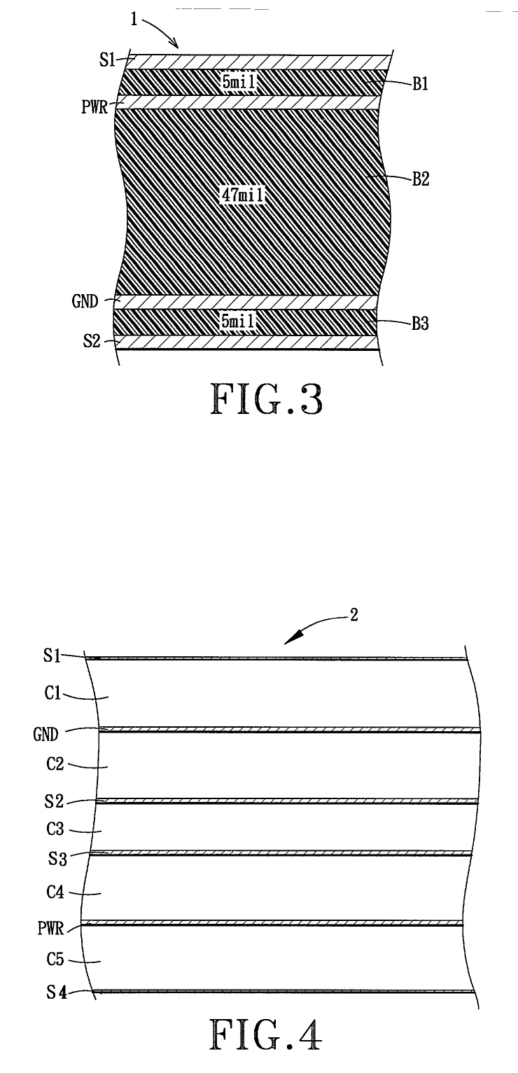

Referring to FIG. 3, the first preferred embodiment of a multi-layer circuit board 1 according to the present invention is shown to comprise: first, second and third insulating substrates (B1), (B2), (B3) disposed sequentially one above the other; a first signal wiring layer (S1) disposed on one side of the first insulating substrate (B1) opposite to the second insulating substrate (B2); a power metal layer (PWR) disposed between the first and second insulating substrates (B1), (B2); a ground metal layer (GND) disposed between the second and third insulating substrates (B2), (B3); and a second signal wiring layer (S2) disposed on one side of the third insulating substrate (B3) opposite to the second insulating substrate (B2). The first and second signal wiring layers (S1), (S2) are adapted for mounting electrical components (not shown) thereon. In general, the second insulating substrate (B2) is a thin core, whereas the first and third insulating substrates (B1), (B3) are prepreg layers.

As mentioned hereinbefore, the resistances of the first and second signal wiring layers (S1), (S2) relative to the adjacent one of the power metal layer (PWR) and the ground metal layer (GND) are preferably within the range of 25.2 to 30.8 ohms determined by Intel in order to be suitable for high-speed low-impedance signal transmission. However, if the thickness (H) of each of the first, second and third insulating substrates (A1), (A2), (A3) of the conventional multi-layer circuit board is reduced, or if the dielectric coefficient (E) of each of the first, second and third insulating substrates (A1), (A2), (A3) is increased to reduce the resistances of the first and second signal wiring layers (S1), (S2) with respect to the respective one of the power metal layer (PWR) and the ground metal layer (GND), since the total thickness of conventional multi-layer circuit boards and the thickness of each insulating substrate have to comply with manufacturing standards set forth in the industry, an excessive reduction in the thickness of the insulating substrates will result in undesirable changes in the characteristics of the conventional multi-layer circuit board, thereby necessitating considerable alterations to the entire layout. In addition, the total thickness of the conventional multi-layer circuit board will not comply with industry standards.

In the present embodiment, the first and third insulating substrates (B1), (B3) that are disposed adjacent to the first and second signal wiring layers (S1), (S2), respectively, are chosen to be made from a first insulator material that has a dielectric coefficient greater than 4.5, which is the dielectric coefficient of a second insulator material, such as glass fiber reinforced epoxy resin, generally used to make the first, second and third insulating substrates of the conventional multi-layer circuit board, and that has a relatively low dissipation factor so as not to result in a substantial change in the thickness of each of the insulating substrates and in the total thickness of the multi-layer circuit board. Moreover, in order to facilitate the press-bonding operation during the manufacture of the multi-layer circuit board according to this invention, the first and third insulating substrates (B1), (B3) are controlled to have equal thickness.

While the following preferred embodiment is illustrated using a 1.6 mm multi-layer circuit board comprising four signal wiring and metal layers, it will be apparent that the multi-layer circuit board of this invention is not limited to 1.6 mm multi-layer circuit boards having four signal wiring and metal layers.

In the embodiment of FIG. 3, it is assumed that the second insulating substrate (B2) is made from glass fiber reinforced epoxy resin, which has a dielectric coefficient of 4.5, whereas the first and second insulating substrates (B1), (B3) are made from ceramic filled polytetrafluoroethylene, which has a dielectric coefficient of 10.2 and a dissipation factor of 0.002. In order to calculate the width (W) of the traces of the first and second signal wiring layers (S1), (S2) using the following formula (2), which, as noted, is the same as the previous formula (1), it is assumed that the resistance of the first signal wiring layer (S1) relative to the power metal layer (PWR) is Z1 and is equal to 28 ohms. Under the condition that the first and third insulating substrates (B1), (B3) are symmetrical in construction, the resistance of the second signal wiring layer (S2) relative to the ground metal layer (GND) is Z2 and is equal to Z1.

Z1=87(E+1.41)^{-1/2} ln{5.98H/(0.8W+T1)} (2)

wherein E is the dielectric coefficient of the adjacent insulating substrate and is equal to 10.2, H is the thickness of the adjacent insulating substrate and is equal to 5 mil, and T1 is the thickness of the signal wiring layer and is equal to 0.7 mil.

It is found that the width (W) of traces of the first and second signal wiring layers (S1), (S2) is 12 mil. Therefore, the distance between traces of the respective signal wiring layer can be reduced to 12 mil according to the ratio recognized in the industry.

In the present invention, as the insulating substrates that are disposed adjacent to the high-speed low-impedance signal wiring layers are made from the first insulator material with the higher dielectric coefficient and relatively low dissipation factor, the resistances of the signal wiring layers relative to the adjacent metal layers can be controlled to be within the range of 28±10% ohms recommended by Intel for high-speed low-impedance signal transmission, such as that required by RAMBUS DRAM layouts recently launched by Intel, without having to increase the width of the traces of the signal wiring layers. Thus, the area on the signal wiring layers can be effectively utilized for layout purposes. Besides, there is no need to change the thickness of the insulating substrates so that the total thickness of the multi-layer circuit board can be maintained to comply with manufacturing standards set forth in the industry.

It should be noted that the use of the first insulator material with the higher dielectric coefficient and relatively low dissipation factor in the present invention to form the insulating substrates adjacent to the high-speed low-impedance signal wiring layers, with the rest of the insulating substrates being made from glass fiber reinforced epoxy resin which is generally adopted in the prior art, can be similarly applied to multi-layer circuit boards of other types to comply with the theoretical range recommended by Intel while maintaining a standard total thickness of the circuit board. Hence, the number of the metal and signal wiring layers as well as that of the insulating substrates of the multi-layer circuit board of the present invention should not be limited to the embodiment illustrated hereinbefore, and can vary as shown in the following embodiments.

In general, to facilitate the press-bonding operation, a multi-layer circuit board has an even total number of metal and signal wiring layers. For example, in a multi-layer circuit board with six metal and signal wiring layers, three or four of those layers can serve as the signal wiring layers. However, in actual practice, it is possible that only some of the signal wiring layers will be used for high-speed low-impedance signal transmission. Therefore, only those insulating substrates that are adjacent to the high-speed low-impedance signal wiring layers are required to be formed from the first insulator material with the higher dielectric coefficient and relatively low dissipation factor in accordance with the present invention. Moreover, in view of the shielding characteristics of the power and ground metal layers, any of the signal wiring layers adjacent to the power and ground metal layers can be selected for layout of high-speed low-impedance circuits.

Referring to FIG. 4, the second preferred embodiment of a multi-layer circuit board 2 according to the present invention is shown to comprise: first, second, third, fourth and fifth insulating substrates (C1), (C2), (C3), (C4), (C5) disposed sequentially one above the other; a first signal wiring layer (S1) disposed on one side of the first insulating substrate (C1) opposite to the second insulating substrate (C2) a ground metal layer (GND) disposed between the first and second insulating substrates (C1), (C2); a second signal wiring layer (S2) disposed between the second and third insulating substrates (C2), (C3); a third signal wiring layer (S3) disposed between the third and fourth insulating substrates (C3), (C4); a power metal layer (PWR) disposed between the fourth and fifth substrates (C4), (C5); and a fourth signal wiring layer (S4) disposed on one side of the fifth insulating substrate (C5) opposite to the fourth insulating substrate (C4).

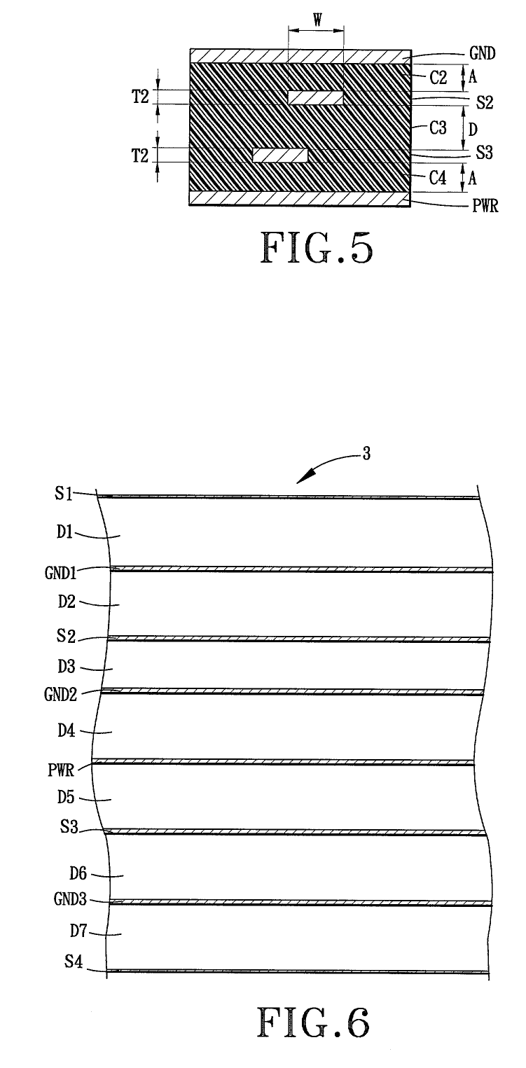

In the second preferred embodiment, the first and fifth insulating substrates (C1), (C5), which are respectively adjacent to the first and fourth signal wiring layers (S1), (S4), are chosen to be made from the first insulator material with the higher dielectric coefficient and relatively low dissipation factor (such as ceramic filled polytetrafluoroethylene) so as to provide the first and fourth signal wiring layers (S1), (S4) with high-speed low-impedance signal transmission characteristics, while maintaining the advantages of the first preferred embodiment. With further reference to FIG. 5, the second signal wiring layer (S2) has a resistance (Z₃) relative to the ground metal layer (GND), and the third signal wiring layer (S3) has a resistance (Z₄) relative to the power metal layer (PWR). As the second and third signal wiring layers (S2), (S3) are symmetrically disposed on the circuit board of FIG. 4, Z₃ is equivalent to Z₄ and can be expressed by the following formula (3). It is noted herein that, according to manufacturing standards set forth in the industry, the thickness of each of the first and fourth signal wiring layers (S1), (S4) is 0.7 mil, and that of the second and third signal wiring layers (S2), (S3), as well as that of the power metal layer (PWR) and ground metal layer (GND) is equal to 1.4 mil.

$${Z}_{3} = \frac{80 [ 1 ( \frac{A}{4 ( A + D + {T}_{2} )} ) ]}{\sqrt{E}} ln \{ \frac{1.9 ( 2 A + {T}_{2} )}{0.8 W + {T}_{2}} \} \qquad 3$$

wherein E is the dielectric coefficient of the adjacent insulating substrates, A is the distance to the adjacent metal layer, T₂ is the thickness of the respective one of the second and third signal wiring layers and is equal to 1.4 mil, D is the thickness of the third insulating substrate, and W is the width of traces of the second and third signal wiring layers.

From the above formula (3), it can be seen that, when the second, third and fourth insulating substrates (C2), (C3), (C4) are chosen to be made from the first insulator material with the higher dielectric coefficient and relatively low dissipation factor, the resistances of the second and third signal wiring layers (S2), (S3) relative to the ground and power metal layers (GND), (PWR) can be reduced to be within the range recommended for high-speed low-impedance signal transmission, without incurring an increase in the width of the traces or the distance between the adjacent traces of the second and third signal wiring layers (S2), (S3), and while maintaining a standard total circuit board thickness.

Referring to FIG. 6, the third preferred embodiment of a multi-layer circuit board 3 according to the present invention is shown to include: first, second, third, fourth, fifth, sixth and seventh insulating substrates (D1), (D2), (D3), (D4), (D5) (D6), (D7) disposed sequentially one above the other; a first signal wiring layer (S1) disposed on one side of the first insulating substrate (D1) opposite to the second insulating substrate (D2); a first ground metal layer (GND1) disposed between the first and second insulating substrates (D1), (D2); a second signal wiring layer (S2) disposed between the second and third insulating substrates (D2), (D3); a second ground metal layer (GND2) disposed between the third and fourth insulating substrates (D3), (D4); a power metal layer (PWR) disposed between the fourth and fifth insulating substrates (D4), (D5); a third signal wiring layer (S3) disposed between the fifth and sixth insulating substrates (D5), (D6); a third ground metal layer (GND3) disposed between the sixth and seventh insulating substrates (D6), (D7); and a fourth signal wiring layer (S4) disposed on one side of the seventh insulating substrate (D7) opposite to the sixth insulating substrate (D6). According to the formula (2) mentioned in connection with the description of the first preferred embodiment, when the first and fourth signal wiring layers (S1), (S4) are designated for high-speed low-impedance signal transmission, the first and seventh insulating substrates (D1), (D7) are chosen to be made from the first insulator material with the higher dielectric coefficient and relatively low dissipation factor, such as ceramic filled polytetrafluoroethylene, whereas the second, third, fourth, fifth and sixth insulating substrates (D2), (D3), (D4), (D5), (D6) are made from the second insulator material with the lower dielectric coefficient, such as glass fiber reinforced epoxy resin. In this way, while maintaining a standard total circuit board thickness, the resistances of the first and fourth signal wiring layers (S1), (S4) relative to the adjacent ground metal layers (GND1), (GND3) can be controlled to be within the range recommended for high-speed low-impedance signal transmission.

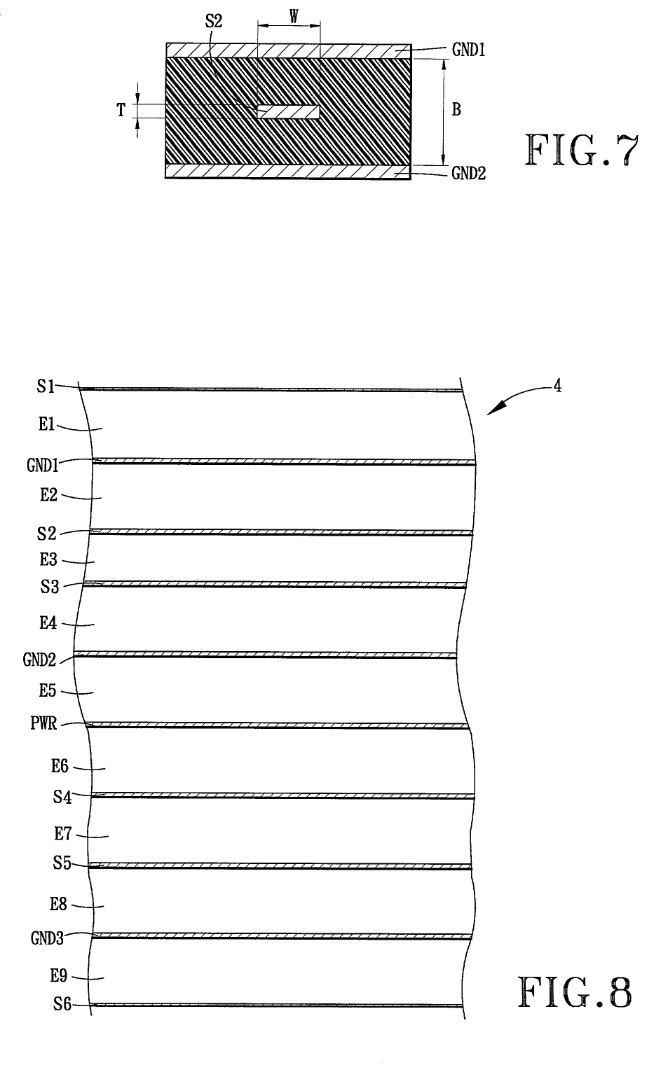

Moreover, with further reference to FIG. 7, when the second signal wiring layer (S2) is designated for high-speed low-impedance signal transmission, the second and third insulating substrates (D2), (D3) that are disposed adjacent thereto are chosen to be made from the first insulator material. In a similar manner, the fifth and sixth insulating substrates (D5), (D6) that are adjacent to the third signal wiring layer (S3) can be made from the first insulator material to make the third signal wiring layer (S3) suitable for high-speed low-impedance signal transmission. As the multi-layer circuit board 3 is formed by press-bonding, the resistance (Z₅) of the second signal wiring layer (S2) relative to the first ground metal layer (GND1) and the second ground metal layer (GND2) is equivalent to the resistance (Z₆) of the third signal wiring layer (S3) relative to the power metal layer (PWR) and the third ground metal layer (GND3). The resistance (Z₅) can be calculated using the following formula (4):

$${Z}_{5} = \frac{60}{\sqrt{E}} ln \{ \frac{4 B}{0.67 π W ( 0.8 + \frac{T}{W} )} \} \qquad ( 4 )$$

wherein E is the dielectric coefficient of the adjacent insulating substrates and is equal to 10.2, W is the width of traces of the second signal wiring layer, T is the thickness of the second signal wiring layer and is equal to 1.4 mil, and B is the distance between the adjacent ground metal layers (GND1), (GND2) From the above formula (4), it can be seen that the resistance (Z5) of the second signal wiring layer (S2) will decrease with an increase in the dielectric coefficient of the second and third insulating substrates (D2), (D3) so that there is no need to augment the width (W) to achieve relatively low resistance with respect to the adjacent ground metal layers (GND1), (GND2). Hence, in the third preferred embodiment, in addition to forming the first and seventh insulating substrates (D1), (D7) from the first insulator material to make the first and fourth signal wiring layers (S1), (S4) suitable for high-speed low-impedance signal transmission, the second and third insulating substrates (D2), (D3) and/or the fifth and sixth insulating substrates (D5), (D6) can be chosen to be formed from the first insulator material to make the second signal wiring layer (S2) and/or the third signal wiring layer (S3) also suitable for high-speed low-impedance signal transmission.

Referring to FIG. 8, the fourth preferred embodiment of a multi-layer circuit board 4 according to the present invention is shown to comprise: first, second, third, fourth, fifth, sixth, seventh, eighth, and ninth insulating substrates (E1), (E2), (E3), (E4), (E5), (E6), (E7), (E8), (E9) disposed sequentially one above the other; a first signal wiring layer (S1) disposed on one side of the first insulating substrate (E1) opposite to the second insulating substrate (E2); a first ground metal layer (GND1) disposed between the first and second insulating substrates (E1), (E2); a second signal wiring layer (S2) disposed between the second and third insulating substrates (E2), (E3); a third signal wiring layer (S3) disposed between the third and fourth insulating substrates (E3), (E4); a second ground metal layer (GND2) disposed between the fourth and fifth insulating substrates (E4), (E5); a power metal layer (PWR) disposed between the fifth and sixth insulating substrates (E5), (E6); a fourth signal wiring layer (S4) disposed between the sixth and seventh insulating substrates (E6), (E7); a fifth signal wiring layer (S5) disposed between the seventh and eighth insulating substrates (E7), (E8); a third ground metal layer (GND3) disposed between the eight and ninth insulating substrates (E8), (E9); and a sixth signal wiring layer (S6) disposed on one side of the ninth insulating substrate (E9) opposite to the eight insulating substrate (E8).

In this embodiment, the multi-layer circuit board 4 includes six signal wiring layers (S1) to (S6), each of which has at least one side disposed adjacent to one of the ground and power metal layers.

In the fourth preferred embodiment, when the first and sixth signal wiring layers (S1), (S6) are designated for high-speed low-impedance signal transmission, the first and ninth insulating substrates (E1), (E9) are chosen to be made from the first insulator material with the higher dielectric coefficient and relatively low dissipation factor, such as ceramic filled polytetrafluoroethylene, whereas the other insulating substrates are made from the second insulator material with the lower dielectric coefficient. In this way, while maintaining a standard total circuit board thickness, the resistances of the first and sixth signal wiring layers (S1), (S6) relative to the adjacent ground metal layers (GND1), (GND3) can be controlled to be within the range recommended for high-speed low-impedance signal transmission.

Moreover, when the second and third signal wiring layers (S2), (S3) are designated for high-speed low-impedance signal transmission, the second, third and fourth insulating substrates (E2), (E3), (E4) are chosen to be made from the first insulator material, whereas the other insulating substrates are made from the second insulator material. In the same manner, while maintaining a standard total circuit board thickness, the resistances of the second and third signal wiring layers (S2), (S3) relative to the adjacent ground metal layers (GND1), (GND2) can be controlled to be within the range recommended for high-speed low-impedance signal transmission.

Furthermore, when the fourth and fifth signal wiring layers (S4), (S5) are designated for high-speed low-impedance signal transmission, the sixth, seventh and eighth insulating substrates (E6), (E7), (E8) can be chosen to be made from the first insulator material, whereas the other insulating substrates are made from the second insulator material. Likewise, while maintaining a standard total circuit board thickness, the resistances of the fourth and fifth signal wiring layers (S4), (S5) relative to the adjacent metal layers (PWR), (GND3) can be controlled to be within the range recommended for high-speed low-impedance signal transmission.

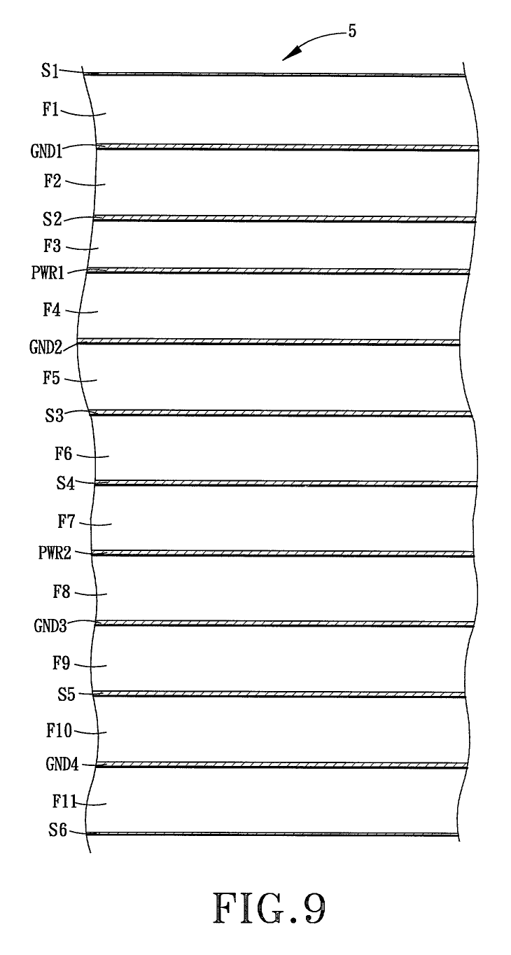

Referring to FIG. 9, the fifth preferred embodiment of a multi-layer circuit board 5 according to the present invention is shown to comprise: first, second, third, fourth, fifth, sixth, seventh, eighth, ninth, tenth, and eleventh insulating substrates (F1), (F2), (F3), (F4), (F5), (F6), (F7), (F8), (F9), (F10), (F11) disposed sequentially one above the other; a first signal wiring layer (S1) disposed on one side of the first insulating substrate (F1) opposite to the second insulating substrate (F2); a first ground metal layer (GND1) disposed between the first and second insulating substrates (F1), (F2); a second signal wiring layer (S2) disposed between the second and third insulating substrates (F2), (F3); a first power metal layer (PWR) disposed between the third and fourth insulating substrates (F3), (F4); a second ground metal layer (GND2) disposed between the fourth and fifth insulating substrates (F4), (F5); a third signal wiring layer (S3) disposed between the fifth and sixth insulating substrates (F5), (F6); a fourth signal wiring layer (S4) disposed between the sixth and seventh insulating substrates (F6), (F7); a second power metal layer (PWR2) disposed between the seventh and eighth insulating substrates (F7), (F8); a third ground metal layer (GND3) disposed between the eight and ninth insulating substrates (F8), (F9); a fifth signal wiring layer (S5) disposed between the ninth and tenth insulating substrates (F9), (F10); a fourth ground metal layer (GND4) disposed between the tenth and eleventh insulating substrates (F10), (F11); and a sixth signal wiring layer (S6) disposed on one side of the eleventh insulating substrate (F11) opposite to the tenth insulating substrate (F10).

In the fifth preferred embodiment, when the first and sixth signal wiring layers (S1), (S6) are designated for high-speed low-impedance signal transmission, the first and eleventh insulating substrates (F1), (F11) are chosen to be made from the first insulator material with the higher dielectric coefficient and relatively low dissipation factor (such as ceramic filled polytetrafluoroethylene), whereas the other insulating substrates are made from the second insulator material with the lower dielectric coefficient, such as glass fiber reinforced epoxy resin. In this way, while maintaining a standard total circuit board thickness, the resistances of the first and sixth signal wiring layers (S1), (S6) relative to the adjacent ground metal layers (GND1), (GND4) can be controlled to be within the range recommended for high-speed low-impedance signal transmission.

Moreover, when the second signal wiring layer (S2) is designated for high-speed low-impedance signal transmission, the second and third insulating substrates (F2), (F3) are chosen to be made from the first insulator material, whereas the other insulating substrates are made from the second insulator material. In the same manner, while maintaining a standard total circuit board thickness, the resistance of the second signal wiring layer (S2) relative to the adjacent metal layers (GND1), (PWR1) can be controlled to be within the range recommended for high-speed low-impedance signal transmission.

Furthermore, when the fifth signal wiring layer (S5) is designated for high-speed low-impedance signal transmission, the ninth and tenth insulating substrates (F9), (F10) are chosen to be made from the first insulator material, whereas the other insulating substrates are made from the second insulator material. Likewise, while maintaining a standard total circuit board thickness, the resistance of the fifth signal wiring layer (S5) relative to the adjacent ground metal layers (GND3), (GND4) can be controlled to be within the range recommended for high-speed low-impedance signal transmission.

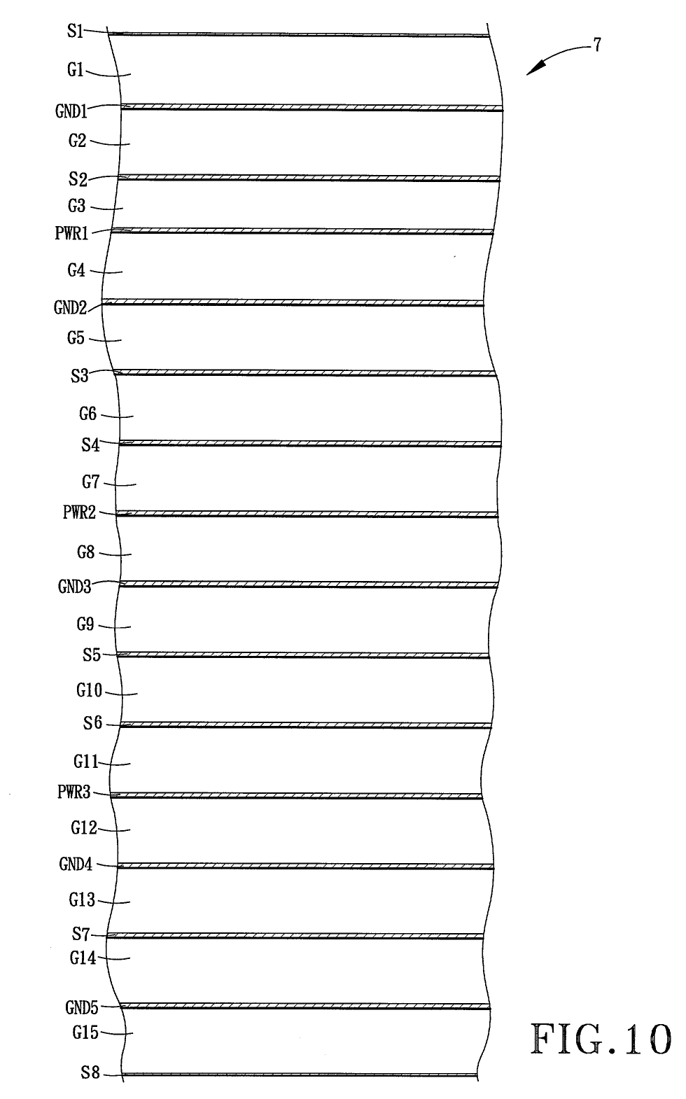

In addition, when the third and fourth signal wiring layers (S3), (S4) are designated for high-speed low-impedance signal transmission, the fifth, sixth and seventh insulating substrates (F5), (F6), (F7) can be chosen to be made from the first insulator material, whereas the other insulating substrates are made from the second insulator material. Similarly, while maintaining a standard total circuit board thickness, the resistances of the third and fourth signal wiring layers (S3), (S4) relative to the adjacent metal layers (GND2), (PWR2) can be controlled to be within the range recommended for high-speed low-impedance signal transmission. Referring to FIG. 10, the sixth preferred embodiment of a multi-layer circuit board 6 according to the present invention is shown to comprise: first, second, third, fourth, fifth, sixth, seventh, eighth, ninth, tenth, eleventh, twelfth, thirteenth, fourteenth, and fifteenth insulating substrates (G1), (G2), (G3), (G4), (G5), (G6), (G7), (G8), (G9), (G10), (G11), (G12), (G13), (G14), (G15) disposed sequentially one above the other; a first signal wiring layer (S1) disposed on one side of the first insulating substrate (G1) opposite to the second insulating substrate (G2); a first ground metal layer (GND1) disposed between the first and second insulating substrates (G1), (G2); a second signal wiring layer (S2) disposed between the second and third insulating substrates (G2), (G3); a first power metal layer (PWR1) disposed between the third and fourth insulating substrates (G3), (G4); a second ground metal layer (GND2) disposed between the fourth and fifth insulating substrates (G4), (G5); a third signal wiring layer (S3) disposed between the fifth and sixth insulating substrates (G5), (G6); a fourth signal wiring layer (S4) disposed between the sixth and seventh insulating substrates (G6), (G7); a second power metal layer (PWR2) disposed between the seventh and eighth insulating substrates (G7), (G8); a third ground metal layer (GND3) disposed between the eighth and ninth insulating substrates (G8), (G9); a fifth signal wiring layer (S5) disposed between the ninth and tenth insulating substrates (G9), (G10); a sixth signal wiring layer (S6) disposed between the tenth and eleventh insulating substrates (G10), (G11); a third power metal layer (PWR3) disposed between the eleventh and twelfth insulating substrates (G11), (Gl2); a fourth ground metal layer (GND4) disposed between the twelfth and thirteenth insulating substrates (G12), (G13); a seventh signal wiring layer (S7) disposed between the thirteenth and fourteenth insulating substrates (G13), (G14); a fifth ground metal layer (GND5) disposed between the fourteenth and fifteenth insulating substrates (G14), (G15); and an eighth signal wiring layer (S8) disposed on one side of the fifteenth insulating substrate (G15) opposite to the fourteenth insulating substrate (G14).

In the sixth preferred embodiment, when the first and eighth signal wiring layers (S1), (S8) are designated for high-speed low-impedance signal transmission, the first and fifteenth insulating substrates (G1), (G15) are chosen to be made from the first insulator material with the higher dielectric coefficient and relatively low dissipation factor (such as ceramic filled polytetrafluoroethylene), whereas the other insulating substrates are made from the second insulator material with the lower dielectric coefficient (such as glass fiber reinforced epoxy resin). In this way, while maintaining a standard total circuit board thickness, the resistances of the first and eighth signal wiring layers (S1), (S8) relative to the adjacent ground metal layers (GND1), (GND5) can be controlled to be within the range recommended for high-speed low-impedance signal transmission.

Moreover, when the second signal wiring layer (S2) is designated for high-speed low-impedance transmission, the second and third insulating substrates (G2), (G3) are chosen to be made from the first insulator material, whereas the other insulating substrates are made from the second insulator material. In the same manner, while maintaining a standard total circuit board thickness, the resistance of the second signal wiring layer (S2) relative to the adjacent metal layers (GND1), (PWR1) can be controlled to be within the range recommended for high-speed low-impedance signal transmission.

Furthermore, when the seventh signal wiring layer (S7) is designated for high-speed low-impedance signal transmission, the thirteenth and fourteenth insulating substrates (G13), (G14) are chosen to be made from the first insulator material, whereas the other insulating substrates are made from the second insulator material. Likewise, while maintaining a standard total circuit board thickness, the resistance of the seventh signal wiring layer (S7) relative to the adjacent ground metal layers (GND4), (GND5) can be controlled to be within the range recommended for high-speed low-impedance signal transmission.

In addition, when the third and fourth signal wiring layers (S3), (S4) are designated for high-speed low-impedance signal transmission, the fifth, sixth and seventh insulating substrates (G5), (G6), (G7) can be chosen to be made from the first insulator material, whereas the other insulating substrates are made from the second insulator material. Similarly, while maintaining a standard total circuit board thickness, the resistances of the third and fourth signal wiring layers (S3), (S4) relative to the adjacent metal layers (GND2), (PWR2) can be controlled to be within the range recommended for high-speed low-impedance signal transmission.

Furthermore, when the fifth and sixth signal wiring layers (S5), (S6) are designated for high-speed low-impedance signal transmission, the ninth, tenth and eleventh insulating substrates (G9), (G10), (G11) can be chosen to be made from the first insulator material, whereas the other insulating substrates are made from the second insulator material. Similarly, while maintaining a standard total circuit board thickness, the resistances of the fifth and sixth signal wiring layers (S5), (S6) relative to the adjacent metal layers (GND3), (PWR3) can be controlled to be within the range recommended for high-speed low-impedance signal transmission.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

We claim:

1. A multi-layer circuit board comprising:
at least two metal layers and at least two signal wiring layers disposed one above the other, at least one of said metal layers being a ground metal layer, at least one of said metal layers being a power metal layer; and
a plurality of insulating substrates disposed sequentially one above the other, each adjacent pair of said metal layers and said signal wiring layers being spaced apart by one of said insulating substrates;
wherein at least one of said signal wiring layers is suitable for high-speed low-impedance signal transmission and has a resistance relative to an adjacent one of said metal layers that is within the range of 25.2 to 30.8 ohms;
said at least one of said signal wiring layers that is suitable for high-speed low-impedance signal transmission being separated from the adjacent one of said metal layers by an adjacent one of said insulating substrates, which is made from a first insulator material having a first dielectric coefficient; the other ones of said insulating substrates that are not adjacent to said at least one of said signal wiring layers being made of a second insulator material having a second dielectric coefficient that is lower than the first dielectric coefficient.

2. The multi-layer circuit board of claim 1, wherein the second dielectric coefficient is about 4.5.

3. The multi-layer circuit board of claim 1, wherein the first dielectric coefficient is greater than 4.5.

4. The multi-layer circuit board of claim 1, wherein the second insulator material is glass fiber reinforced epoxy resin.

5. The multi-layer circuit board of claim 1, wherein the first insulator material is ceramic filled polytetrafluoroethylene.

6. The multi-layer circuit board of claim 1, wherein the first insulator material has a dissipation factor of about 0.002.

7. The multi-layer circuit board of claim 1, wherein:
said insulating substrates include first, second and third insulating substrates disposed sequentially one above the other;
said signal wiring layers including a first signal wiring layer disposed on one side of said first insulating substrate opposite to said second insulating substrate, and a second signal wiring layer disposed on one side of said third insulating substrate opposite to said second insulating substrate;
said power metal layer being disposed between said first and second insulating substrates;
said ground metal layer being disposed between said second and third insulating substrates;
said first and third insulating substrates being made from the first insulator material;
said second insulating substrate being made from the second insulator material.

8. The multi-layer circuit board of claim 1, wherein:
said insulating substrates include first, second, third, fourth and fifth insulating substrates disposed sequentially one above the other;
said signal wiring layers including a first signal wiring layer disposed on one side of said first insulating substrate opposite to said second insulating substrate, a second signal wiring layer disposed between said second and third insulating substrates, a third signal wiring layer disposed between said third and fourth signal wiring layers, and a fourth signal wiring layer disposed on one side of said fifth insulating substrate opposite to said fourth insulating substrate;
said ground metal layer being disposed between said first and second insulating substrates;
said power metal layer being disposed between said fourth and fifth insulating substrates.

9. The multi-layer circuit board of claim 8, wherein said first and fifth insulating substrates are made from the first insulator material, and said second, third and fourth insulating substrates are made from the second insulator material.

10. The multi-layer circuit board of claim 8, wherein said first and fifth insulating substrates are made from the second insulator material, and said second, third and fourth insulating substrates are made from the first insulator material.

11. The multi-layer circuit board of claim 1, wherein:
said insulating substrates include first, second, third, fourth, fifth, sixth and seventh insulating substrates disposed sequentially one above the other;
said signal wiring layers including a first signal wiring layer disposed on one side of said first insulating substrate opposite to said second insulating substrate, a second signal wiring layer disposed between said second and third insulating substrates, a third signal wiring layer disposed between said fifth and sixth insulating substrates, and a fourth signal wiring layer disposed on one side of said seventh insulating substrate opposite to said sixth insulating substrate;
said metal layers including a first one of said ground metal layers disposed between said first and second insulating substrates, a second one of said ground metal layers disposed between said third and fourth insulating substrates, said power metal layer disposed between said fourth and fifth insulating substrates, and a third one of said ground metal layers disposed between said sixth and seventh insulating substrates.

12. The multi-layer circuit board of claim 11, wherein said first and seventh insulating substrates are made from the first insulator material, and said second, third, fourth, fifth and sixth insulating substrates are made from the second insulator material.

13. The multi-layer circuit board of claim 11, wherein said second and third insulating substrates are made from the first insulator material.

14. The multi-layer circuit board of claim 11, wherein said fifth and sixth insulating substrates are made from the first insulator material.

15. The multi-layer circuit board of claim 11, wherein said second, third, fifth and sixth insulating substrates are made from the first insulator material, and said first, fourth and seventh insulating substrates are made from the second insulator material.

16. The multi-layer circuit board of claim 1, wherein:
said insulating substrates include first, second, third, fourth, fifth, sixth, seventh, eighth and ninth insulating substrates disposed sequentially one above the other;
said signal wiring layers including a first signal wiring layer disposed on one side of said first insulating substrate opposite to said second insulating substrate, a second signal wiring layer disposed between said second and third insulating substrates, a third signal wiring layer disposed between said third and fourth insulating substrates, a fourth signal wiring layer disposed between said sixth and seventh insulating substrates, a fifth signal wiring layer disposed between said seventh and eighth insulating substrates, and a sixth signal wiring layer disposed on one side of said ninth insulating substrate opposite to said eighth insulating substrate;
said metal layers including a first one of said ground metal layers disposed between said first and second insulating substrates, a second one of said ground metal layers disposed between said fourth and fifth insulating substrates, said power metal layer disposed between said fifth and sixth insulating substrates, and a third one of said ground metal layers disposed between said eighth and ninth insulating substrates.

17. The multi-layer circuit board of claim 16, wherein said first and ninth insulating substrates are made from the first insulator material, and said second, third, fourth, fifth, sixth, seventh and eighth insulating substrates are made from the second insulator material.

18. The multi-layer circuit board of claim 16, wherein said second, third and fourth insulating substrates are made from the first insulator material.

19. The multi-layer circuit board of claim 16, wherein said sixth, seventh and eighth insulating substrates are made from the first insulator material.

20. The multi-layer circuit board of claim 16, wherein said second, third, fourth, sixth, seventh and eighth insulating substrates are made from the first insulator material, and said first, fifth and ninth insulating substrates are made from the second insulator material.

21. The multi-layer circuit board of claim 1, wherein:
said insulating substrates include first, second, third, fourth, fifth, sixth, seventh, eighth, ninth, tenth and eleventh insulating substrates disposed sequentially one above the other;
said signal wiring layers including a first signal wiring layer disposed on one side of said first insulating substrate opposite to said second insulating substrate, a second signal wiring layer disposed between said second and third insulating substrates, a third signal wiring layer disposed between said fifth and sixth insulating substrates, a fourth signal wiring layer disposed between said sixth and seventh insulating substrates, a fifth signal wiring layer disposed between said ninth and tenth insulating substrates, and a sixth signal wiring layer disposed on one side of said eleventh insulating substrate opposite to said tenth insulating substrate;
said metal layers including a first one of said ground metal layers disposed between said first and second insulating substrates, a first one of said power metal layers disposed between said third and fourth insulating substrates, a second one of said ground metal layers disposed between said fourth and fifth insulating substrates, a second one of said power metal layers disposed between said seventh and eighth insulating substrates, a third one of said ground metal layers disposed between said eighth and ninth insulating substrates, and a fourth one of said ground metal layers disposed between said tenth and eleventh insulating substrates.

22. The multi-layer circuit board of claim 21, wherein said first and eleventh insulating substrates are made from the first insulator material, and said second, third, fourth, fifth, sixth, seventh, eighth, ninth and tenth insulating substrates are made from the second insulator material.

23. The multi-layer circuit board of claim 21, wherein said second and third insulating substrates are made from the first insulator material.

24. The multi-layer circuit board of claim 21, wherein said ninth and tenth insulating substrates are made from the first insulator material.

25. The multi-layer circuit board of claim 21, wherein said second, third, ninth and tenth insulating substrates are made from the first insulator material, and said first, fourth, fifth, sixth, seventh, eighth and eleventh insulating substrates are made from the second insulator material.

26. The multi-layer circuit board of claim 21, wherein said fifth, sixth and seventh insulating substrates are made from the first insulator material, and said first, second, third, fourth, eighth, ninth, tenth and eleventh insulating substrates are made from the second insulator material.

27. The multi-layer circuit board of claim 1, wherein:
said insulating substrates include first, second, third, fourth, fifth, sixth, seventh, eighth, ninth, tenth, eleventh, twelfth, thirteenth, fourteenth and fifteenth insulating substrates disposed sequentially one above the other;
said signal wiring layers including a first signal wiring layer disposed on one side of said first insulating substrate opposite to said second insulating substrate, a second signal wiring layer disposed between said second and third insulating substrates, a third signal wiring layer disposed between said fifth and sixth insulating substrates, a fourth signal wiring layer disposed between said sixth and seventh insulating substrates, a fifth signal wiring layer disposed between said ninth and tenth insulating substrates, a sixth signal wiring layer disposed between said tenth and eleventh insulating substrates, a seventh signal wiring layer disposed between said thirteenth and fourteenth insulating substrates, and an eighth signal wiring layer disposed on one side of said fifteenth insulating substrate opposite to said fourteenth insulating substrate;
said metal layers including a first one of said ground metal layers disposed between said first and second insulating substrates, a first one of said power metal layers disposed between said third and fourth insulating substrates, a second one of said ground metal layers disposed between said fourth and fifth insulating substrates, a second one of said power metal layers disposed between said seventh and eighth insulating substrates, a third one of said ground metal layers disposed between said eighth and ninth insulating substrates, a third one of said power metal layers disposed between said eleventh and twelfth insulating substrates, a fourth one of said ground metal layers disposed between said twelfth and thirteenth insulating substrates, and a fifth one of said ground metal layers disposed between said fourteenth and fifteenth insulating substrates.

28. The multi-layer circuit board of claim 27, wherein said first and fifteenth insulating substrates are made from the first insulator material, and said second, third, fourth, fifth, sixth, seventh, eighth, ninth, tenth, eleventh, twelfth, thirteenth and fourteenth insulating substrates are made from the second insulator material.

29. The multi-layer circuit board of claim 27, wherein said second and third insulating substrates are made from the first insulator material.

30. The multi-layer circuit board of claim 27, wherein said thirteenth and fourteenth insulating substrates are made from the first insulator material.

31. The multi-layer circuit board of claim 27, wherein said second, third, thirteenth and fourteenth insulating substrates are made from the first insulator material, and said first, fourth, fifth, sixth, seventh, eighth, ninth, tenth, eleventh, twelfth and fifteenth insulating substrates are made from the second insulator material.

32. The multi-layer circuit board of claim 27, wherein said fifth, sixth and seventh insulating substrates are made from the first insulator material.

33. The multi-layer circuit board of claim 27, wherein said ninth, tenth and eleventh insulating substrates are made from the first insulator material.

34. The multi-layer circuit board of claim 27, wherein said fifth, sixth, seventh, ninth, tenth and eleventh insulating substrates are made from the first insulator material, and said first, second, third, fourth, eighth, twelfth, thirteenth, fourteenth and fifteenth insulating substrates are made from the second insulator material.
